(19) United States
(12) Patent Application Publication
(10) Pub. No.: US 2015/0091420 A1
(43) Pub. Date: Apr. 2, 2015

(54) STACKABLE COMPUTER HOUSING ASSEMBLY

(71) Applicant: COOLER MASTER ELECTRONICS (HUI ZHOU) CO., LTD., Guangdong Province (CN)

(72) Inventor: YIN FENG LIU, GUANGDONG PROVINCE (CN)

(73) Assignee: COOLER MASTER ELECTRONICS (HUI ZHOU) CO., LTD., Guangdong Province (CN)

(21) Appl. No.: 14/044,015

(22) Filed: Oct. 2, 2013

(51) Int. Cl. G06F 1/16; H05K 5/02

(52) U.S. Cl. CPC G06F 1/1601; H05K 5/0217
USPC 312/223.2

(57) ABSTRACT

A stackable computer housing assembly includes at least two computer housings. Each of the computer housing has a frame body, two first sliding rails and two second sliding rails. The frame body has a top portion and a bottom portion. The two first sliding rails are assembled at the top portion of the frame body, and the two second sliding rails are assembled at the bottom portion of the frame body. Two of the computer housings slidably engage each other through the two first sliding rails and the two second sliding rails, such that the two computer housings are stackingly coupled. The first sliding rail, the second sliding rail and the frame body are independent pieces. The first sliding rail and the second sliding rail fixed to the frame body by assembly, to facilitate application on different computer housings, have preferred compatibility and reduced production cost.

### BACKGROUND OF THE INVENTION

1. Field of the Invention

The present disclosure relates to a stackable main housing assembly; in particular, to a computer housing assembly which can be stacked according to demand.

2. Description of Related Art

Improvement in technology and materials has advanced development in computer hardware. Computers are no longer merely calculators or program processors. Expansion of computer hardware has greatly increased the functions of computers. Typically, when a user needs to use different software and hardware, multiple computers serving different functions operate simultaneously. In order to organize the computers, some users stack the computers on top of each other.

A conventional stackable modular computer housing mainly uses first sliding portions formed at the top portions of the housings and a second sliding portions formed at the bottom portions of the housings to slidably engage each other, such that multiple housings can be stackingly coupled on each other. However, the first sliding portions and the second sliding portions are integrally formed with the housings, so different types of housings each need a new mold designed with sliding portions. The lack of compatibility increases production costs. Moreover, the first sliding portions and the second sliding portions of the abovementioned stackable modular computer housing are long continuous strips requiring long sliding times when slidably engaging two housings to each other, which is inconvenient to assemble and requires more labor, especially if the interiors of the housings are installed with components which add to the weight of the housings.

Hence, the present inventor believes the above mentioned disadvantages can be overcome, and through devoted research combined with application of theory, finally proposes the present disclosure which has a reasonable design and effectively improves upon the above mentioned disadvantages.

### SUMMARY OF THE INVENTION

The object of the present disclosure is to provide a stackable computer housing assembly applicable to different types of housings, which is flexible, compatible and cost saving.

The object of the present disclosure is to provide a stackable computer housing assembly which can reduce the sliding distance between housings to facilitate assembly and reduce labor time.

In order to achieve the aforementioned objects, the present disclosure provides a stackable computer housing assembly including at least two computer housings, each of which has: a frame body having a top portion and a bottom portion; two first sliding rails assembled on the top portion of the frame body; and two second sliding rails assembled on the bottom portion of the frame body. The corresponding two first sliding rails and two second sliding rails of the at least two computer housings slidably engage, such that the at least two computer housings are stackingly coupled.

Preferably, each of the first sliding rails includes a first rail body and a plurality first protrusions connected to the first rail body at intervals, each of the second sliding rails includes a second rail body and a plurality of second protrusions connected to the second rail body at intervals, and the first rail body and the plurality of first protrusions slidably engage with the second rail body and the second protrusions.

The present disclosure has the following advantages. The first sliding rails and the second sliding rails of the present disclosure are formed independently from the frame body. The first sliding rails and the second sliding rails are fixed onto the frame bodies by assembly so as to be applicable to different types of computer housings be flexible to use, have preferred compatibility and lowered production costs.

Furthermore, the discontinuous design of the first sliding rail and the second sliding rail, namely the interval disposing of the first protrusions and the second protrusions, reduces the sliding distance between the top and bottom computer housings during engagement, facilitating the assembly and reducing labor time.

In order to further the understanding regarding the present disclosure, the following embodiments are provided along with illustrations to facilitate the disclosure of the present disclosure.

### BRIEF DESCRIPTION OF THE DRAWINGS

FIG. 1 shows a perspective exploded diagram of a stackable computer housing assembly according to the present disclosure;

FIG. 2 shows a perspective exploded diagram of a stackable computer housing assembly according to the present disclosure from another perspective;

FIG. 3 shows a perspective exploded diagram of a stackable computer housing assembly according to the present disclosure from yet another perspective;

FIG. 4 is an enlarged view of portion A of FIG. 3;

FIG. 5 is a perspective view of frame bodies separated from portions of sliding rails according to the present disclosure;

FIG. 6 shows a perspective view of an assembled stackable computer housing assembly according to the present disclosure;

FIG. 7 shows a cross-sectional view of two separated computer housings according to the present disclosure; and

FIG. 8 shows a cross-sectional view of two engaged computer housings according to the present disclosure.

### DETAILED DESCRIPTION OF THE PREFERRED EMBODIMENTS

The aforementioned illustrations and following detailed descriptions are exemplary for the purpose of further explaining the scope of the present disclosure. Other objectives and advantages related to the present disclosure will be illustrated in the subsequent descriptions and appended drawings.

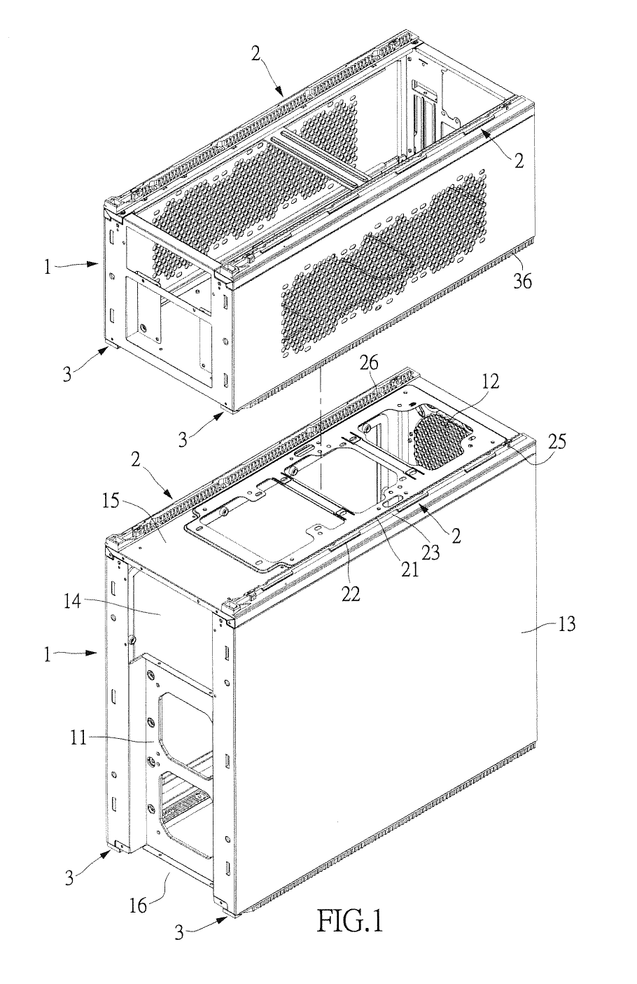

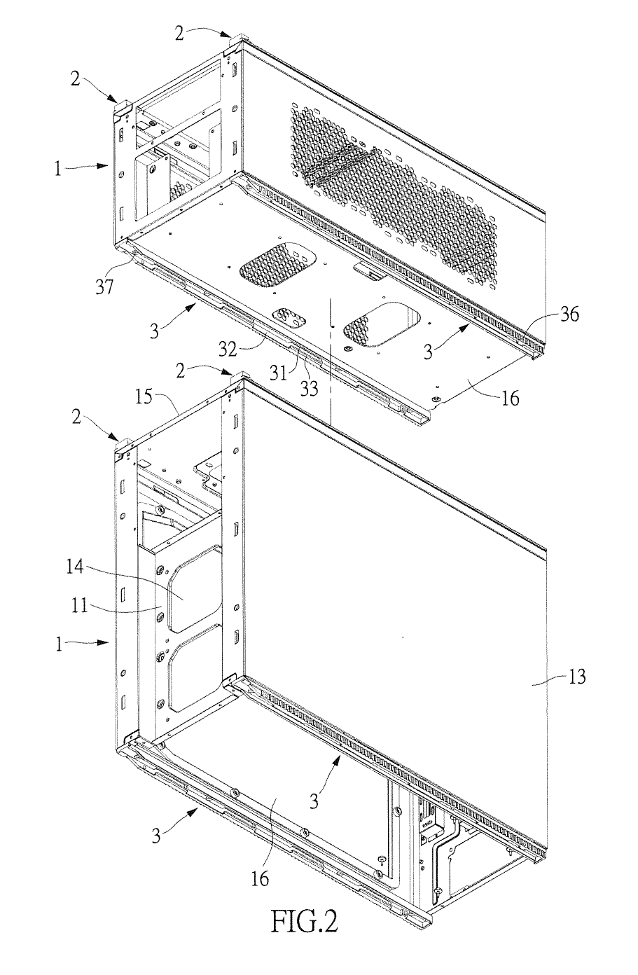

Referring to FIG. 1 and FIG. 2, the present disclosure provides a stackable computer housing assembly including at least two computer housings. The present embodiment discloses two computer housings. However the present disclosure is not limited thereto and can have three, four or more computer housings. Each of the computer housings has a frame body 1, two first sliding rails 2 and two second sliding rails 3.

The frame body 1 can be a cuboid frame body having a first frame 11 and a second frame 12. The first frame 11 and the second frame 12 are spaced apart at an appropriate distance therebetween. A side board 13 is disposed between the first frame 11 and the second frame 12. The first frame 11, the second frame 12 and the side board 13 define a hollow frame body such that the interior of the frame body 1 forms an accommodating space 14 for accommodating computer parts such as motherboards, processors, RAMS, power supply units, hard drives, disk drives, heat fans, etc. However, the articles disposed in the accommodating space 14 are not limited and can be adjusted according to needs. The shape and structure of the frame body 1 is also not limited, and can be altered as typical frame bodies. The frame body 1 has a top portion 15 and a bottom portion 16. The top portion 15 and the bottom portion 16 are positioned on two sides of the frame body 1 vertically opposite each other. The top portion 15 and the bottom portion 16 can be open or sealed.

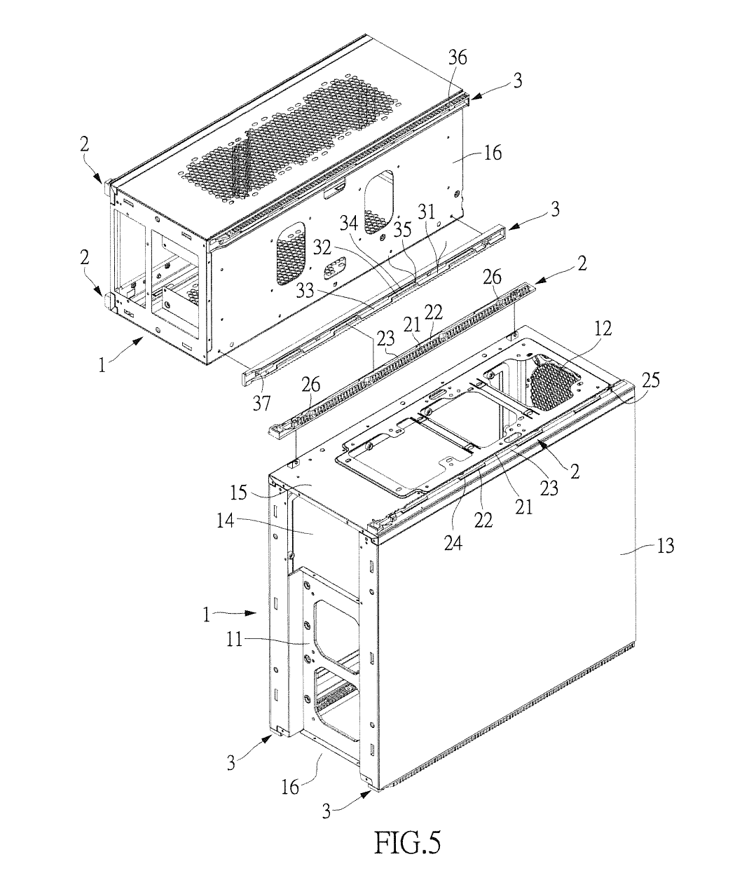

The material of the two first sliding rails 2 are not limited, and can be plastic. The two first sliding rails 2 are disposed at the top portion 15 of the frame body 1. Preferably, the two first sliding rails 2 are disposed at two edges of the top portion 15. The two first sliding rails 2 and the frame body 1 are independent pieces (as shown in FIG. 5). Namely, the two first sliding rails 2 and the frame body 1 are manufactured separately, and then the two first sliding rails 2 are assembled at the top portion 15 of the frame body 1. In the present embodiment, the first sliding rails 2 have a plurality of first fixture holes 26 for screws or rivets to fix the first sliding rails 2 to the top portion 15 of the frame body 1. The dimensions of the two first sliding rails 2 are not limited and can be adjusted according to the specification of the frame body 1.

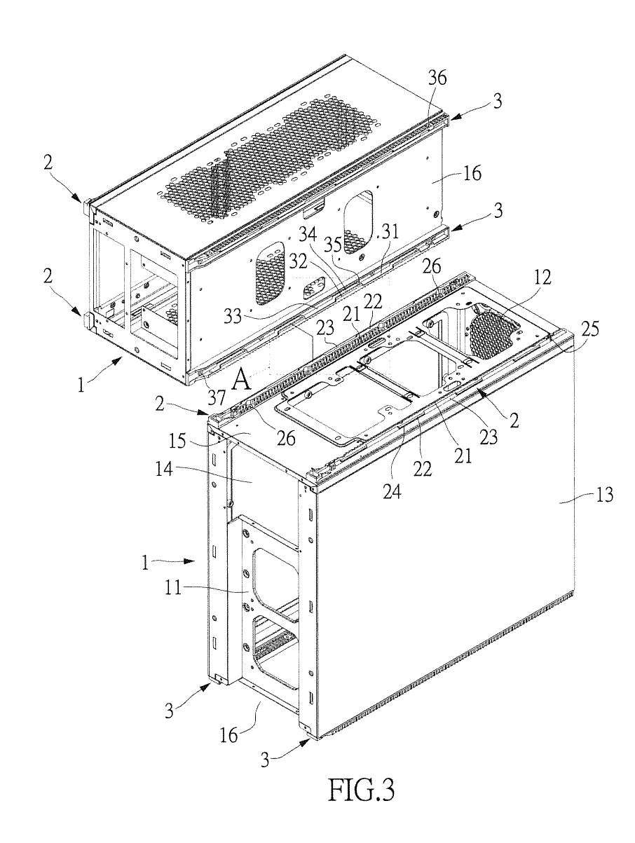

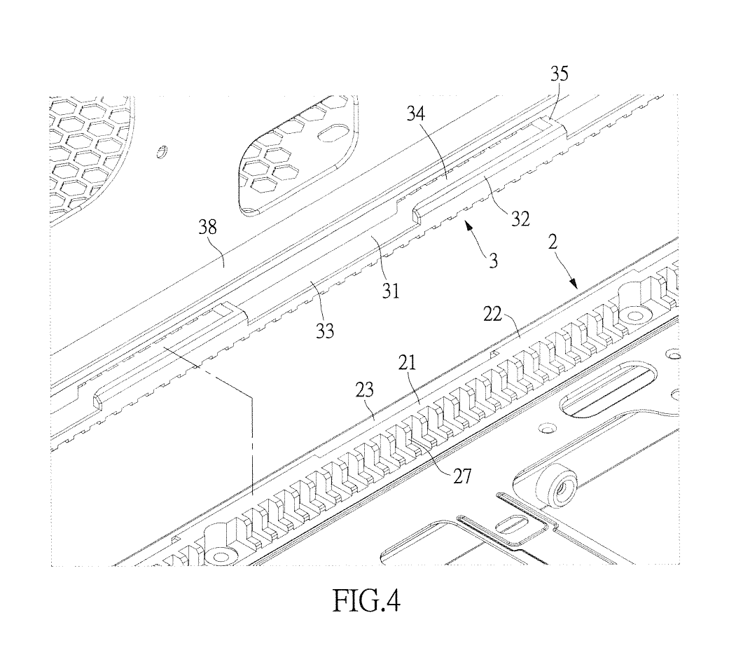

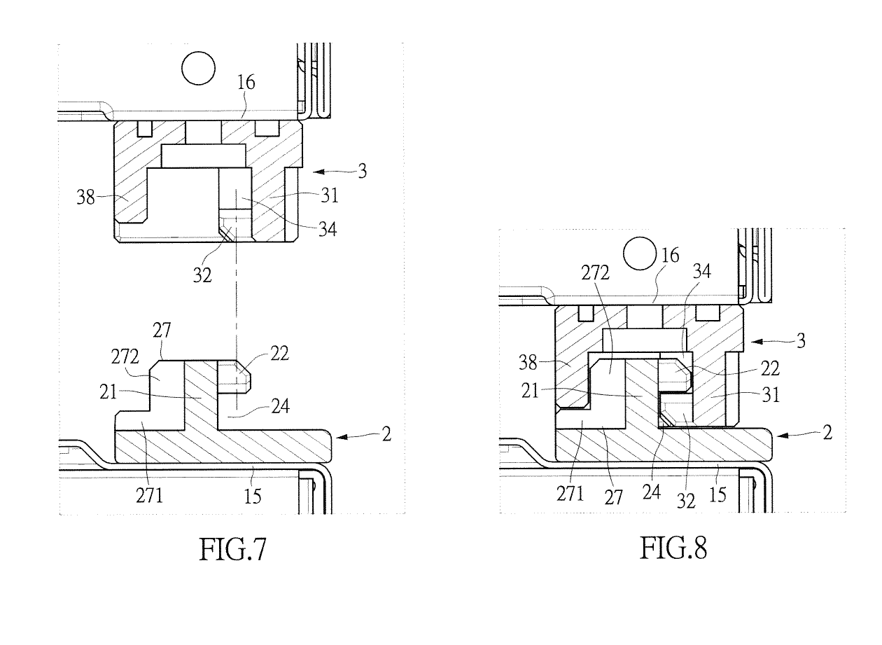

Referring to FIG. 3 and FIG. 4, each of the first sliding rails 2 includes a first rail body 21 and a plurality of first protrusions 22. The cross section of the first rail body 21 can be T-shaped, L-shaped, etc and is not limited thereto. The first protrusions 22 are connected to the first rail body 21. The first protrusions 22 can protrude from one side of the first rail body 21 (as shown in FIG. 7). The first protrusions 22 can extend horizontally. The first protrusions 22 are disposed at intervals such that each two neighboring first protrusions 22 define a first opening 23 therebetween. The first protrusions 22 and the first rail body 21 define a first sliding space 24 therebetween.

The material of the two second sliding rails 3 are not limited, and can be plastic. The two second sliding rails 3 are disposed at the bottom portion 16 of the frame body 1, and correspond to the two first sliding rails 2. Preferably, the two second sliding rails 3 are disposed at two edges of the bottom portion 16. The two second sliding rails 3 and the frame body 1 are independent pieces (as shown in FIG. 5). Namely, the two second sliding rails 3 and the frame body 1 are manufactured separately, and then the two second sliding rails 3 are assembled at the bottom portion 16 of the frame body 1. In the present embodiment the second sliding rails 3 have a plurality of second fixture holes 37 for screws or rivets to fix the second sliding rails 3 to the bottom portion 16 of the frame body 1. The dimensions of the two second sliding rails 3 are not limited and can be adjusted according to the specification of the frame body 1.

Each of the second sliding rails 3 includes a second rail body 31 and a plurality of first protrusions 32. The cross section of the second rail body 31 can be T-shaped, L-shaped, etc and is not limited thereto. The second protrusions 32 are connected to the second rail body 31. The second protrusions 32 can protrude from one side of the second rail body 31. The second protrusions 32 can extend horizontally. The second protrusions 32 are disposed at intervals such that each two neighboring second protrusions 32 define a second opening 33 therebetween. The second protrusions 32 and the second rail body 31 define a second sliding space 34 therebetween. An end on each of the second protrusions 32 can be formed with a blocking end 35 positioned at the terminal end of the second sliding space 34.

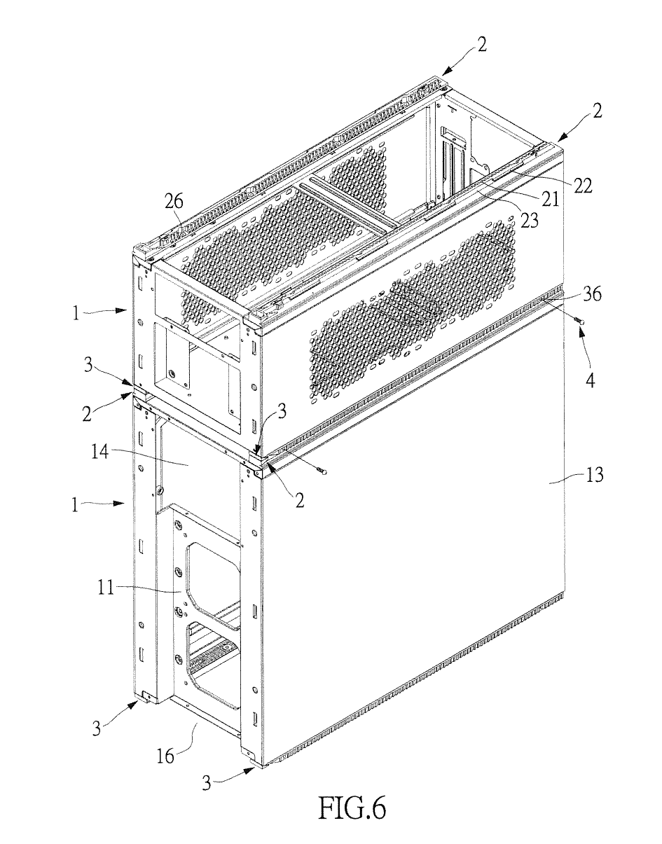

Referring to FIG. 6 to FIG. 8, according to the present disclosure, the top portion 15 and the bottom portion 16 of the frame body 1 are respectively formed with first sliding rails 2 and second sliding rails 3. Therefore, two or more computer housings and be stackingly coupled. The corresponding first sliding rails 2 and the second sliding rails 3 slidably engage each other between two computer housings. Namely, the first rail bodies 21 and the first protrusions 22 are slidingly in contact with the second rail bodies 31 and the second protrusions 32. The first protrusions 22 of the first sliding rails 2 can pass through the respective second openings 33 to rest in the second sliding spaces 34 of the second sliding rails 3 (as shown in FIG. 8). The second protrusions 32 of the second sliding rails 3 can pass through the respective first openings 23 to rest in the first sliding spaces 24 of the first sliding rails 2. The first rail bodies 21 and the first protrusions 22 are slidably in contact with the second rail bodies 31 and the second protrusions 32, retaining each other in an up-down and left-right direction such that the computer housings are securely stackingly coupled on each other.

When one of the first protrusions 22 slides to the terminal end in one of the second sliding spaces 34, the blocking end 35 thereof abuts the first protrusion 22 and retains the first protrusion 22 thereat. Additionally, the first sliding rails 2 can each be formed with at least one first engagement hole 25, and the second sliding rails 3 can each be formed with at least one second engagement hole 36. When two frame bodies 1 slide to a fixed position, the second engagement holes 36 correspond to the respective first engagement holes 25, and fixture units 4 such as screws (as shown in FIG. 6) can be fixed at the first engagement holes 25 and the second engagement holes 36 for providing fixture such that the two frame bodies 2 do not slip.

Additionally, the other side of the first rail bodies 21 of the first sliding rails 2 can be formed with a plurality of blocks 27. The blocks 27 can be L-shaped, namely having horizontal first sections 271 and vertical second sections 272. The second rail bodies 31 of the second sliding rails 3 each extend to form an abutting wall 38. The abutting wall 38 and the second protrusions 32 are disposed with space therebetween. The first sections 271 and the second sections 272 of the blocks 27 respectively abut the underside and the inner side of the abutting wall 38, for guiding and restricting the sliding engagement between the first sliding rail 2 and the second sliding rail 3, such that the first sliding rail 2 and the second sliding rail 3 can slide with respect to each other securely and restrictedly.

The present disclosure provides a stackable computer housing which users can purchase, stack and expand according to need. More expansion space is available and unlike frame-type server expansions, no additional frames need to be purchased for stacked expansions.

The first sliding rails and the second sliding rails of the present disclosure are formed independently from the frame body, and are fixed onto the frame body by assembly. This configuration can be applied to different types of computer housings, is flexible to use, has preferred compatibility and lowered production costs.

The first sliding rails and the second sliding rails of the present disclosure have discontinuous designs. Namely, the first protrusions are disposed at intervals, and the second protrusions are disposed at intervals. The first protrusions can pass through the second openings to rest in the second sliding spaces. The second protrusions can pass through the first openings to rest in the first sliding spaces. The first sliding rail and the second sliding rail do not slide the entire length with respect to each other during engagement, saving travel distance and time and thereby facilitating assembly and reducing labor time.

The descriptions illustrated supra set forth simply the preferred embodiments of the present disclosure; however, the characteristics of the present disclosure are by no means restricted thereto. All changes, alternations, or modifications conveniently considered by those skilled in the art are deemed to be encompassed within the scope of the present disclosure delineated by the following claims.

What is claimed is:

1. A stackable computer housing assembly, including at least two computer housings comprising:
a frame body having a top portion and a bottom portion;
two first sliding rails assembled at the top portion of the frame body; and
two second sliding rails assembled at the bottom portion of the frame body;
wherein the two first sliding rails and the two second sliding rails on two of the computer housings slidably engage each other and the two computer housings are stackingly coupled.

2. The stackable computer housing assembly according to claim 1, wherein each of the first sliding rails has a first rail body and a plurality of first protrusions connected to the first rail body, the first protrusions are arranged at intervals, each of the second sliding rails has a second rail body and a plurality of second protrusions connected to the second rail body, the second protrusions are arranged at intervals and the first rail bodies and the first protrusions are respectively in slidable contact with the second rail bodies and the second protrusions.

3. The stackable computer housing assembly according to claim 2, wherein each one of the first protrusions and the first rail body define a first sliding space therebetween, each one of the second protrusions and the second rail body define a second sliding space therebetween, the first protrusions are accommodated respectively in the second sliding spaces, and the second protrusions are accommodated respectively in the first sliding spaces.

4. The stackable computer housing assembly according to claim 3, wherein each of the two neighboring first protrusions define a first opening therebetween, each of the two neighboring second protrusions define a second opening therebetween, the first protrusions respectively pass through the second openings and are accommodated in the second sliding spaces, and the second protrusions respectively pass through the first openings and are accommodated in the first sliding spaces.

5. The stackable computer housing assembly according to claim 1, wherein each of the first sliding rails is formed with a first fixture hole for fixing the first sliding rail to the top portion of the corresponding frame body.

6. The stackable computer housing assembly according to claim 1, wherein each of the second sliding rails is formed with a second fixture hole for fixing the second sliding rail to the bottom portion of the corresponding frame body.

7. The stackable computer housing assembly according to claim 1, wherein the two first sliding rails are disposed at two edges of the top portion, and the two second sliding rails are disposed at two edges of the bottom portion.

8. The stackable computer housing assembly according to claim 1, wherein the first protrusions protrude from one side of the first rail body and extend horizontally, and the second protrusions protrude from one side of the second rail body and extend horizontally.

9. The stackable computer housing assembly according to claim 1, wherein a terminal end of each one of the second protrusions is formed with a blocking end, the blocking end is positioned at the terminal end in the second sliding space, and when the first protrusions slide in the second sliding space to the terminal end, the first protrusions abut the blocking end and is retained thereat.

10. The stackable computer housing assembly according to claim 1, wherein each one of the first sliding rails is formed with an engagement hole, each one of the second sliding rails is formed with a second engagement hole, and a fixture unit fixes the respective first engagement hole and the respective second engagement hole.

11. The stackable computer housing assembly according to claim 1, wherein the other sides of the first rail bodies of the first sliding rails are each formed with a plurality of blocks, the second rail bodies of the second sliding rails each extend to form an abutting wall, and the blocks abut the abutting walls.

12. The stackable computer housing assembly according to claim 11, wherein each one of the blocks has a horizontal first section and a vertical second section, and the first section and the second section of the block respectively abut the underside and the inner side of one of the abutting wall.
